(19) United States
(12) Patent Application Publication
(10) Pub. No.: US 2025/0006868 A1
(43) Pub. Date: Jan. 2, 2025

(54) DISPLAY DEVICE AND METHOD OF MANUFACTURING THE SAME

(71) Applicant: AUO Corporation, Hsin-Chu (TW)

(72) Inventors: Rong-Sheng TSAI, Hsin-Chu (TW); Wen-Jen Li, Hsin-Chu (TW); Shu-Jiang Liu, Hsin-Chu (TW)

(21) Appl. No.: 18/527,423

(22) Filed: Dec. 4, 2023

(30) Foreign Application Priority Data
Jun. 29, 2023 (TW) 112124402

(51) Int. Cl. H01L 33/44; H01L 25/075

(52) U.S. Cl. CPC H01L 33/44; H01L 25/0753; H01L 2933/0025

(57) ABSTRACT

A display device includes an array substrate, light emitting elements and light shielding units. The light emitting elements are disposed on the array substrate and electrically connected to the array substrate, where each of the light emitting elements has a first surface and a second surface opposite to the first surface. The second surfaces face the array substrate. The light shielding units are disposed on the array substrate and arranged alternately with the light emitting elements, where the light shielding units expose the first surfaces, and each of the light shielding units has a top and a bottom opposite to the top. The bottoms face the array substrate, and a cavity is existed between the bottoms and the array substrate.

### CROSS-REFERENCE TO RELATED APPLICATION

This application claims priority to Taiwan Application Serial Number 112124402, filed Jun. 29, 2023, which is herein incorporated by reference in its entirety.

### BACKGROUND

### Field of Invention

The present disclosure relates to a display device and a method of manufacturing the same. More particularly, the present disclosure relates to a display device including light shielding units and a method of manufacturing the same.

### Description of Related Art

Micro LED displays have the advantages of power saving, high efficiency, high brightness and fast response time. In order to realize mass transfer, in the current transfer process, etching is used to remove the adhesive residues on the micro LEDs transferred to the positioning carrier. Although the aforementioned method can remove the adhesive residues, it is also easy to damage the adhesive between the positioning carrier and the micro LEDs, causing the micro LEDs on the positioning carrier to shift when they are bonded to the array substrate, resulting in the micro LEDs fail to light up and dark spots occur, which in turn reduces the yield.

### SUMMARY

At least one embodiment of the present disclosure provides a display device, which can help to reduce the chance of damage to the adhesive between the carrier and the light emitting elements, and thus improves the yield.

Another embodiment of the present disclosure provides a method of manufacturing the abovementioned display device.

The manufacturing method of the display device according to at least one embodiment of the present disclosure includes the following steps. A first carrier, a first adhesive, and light emitting elements are provided, where the first adhesive is disposed between the light emitting elements and the first carrier, and attaches the light emitting elements to the first carrier. A second carrier and a second adhesive are provided, where the second adhesive is disposed on the second carrier. At least two of the light emitting elements are transferred from the first carrier to the second carrier, each of the at least two light emitting elements has a first surface and a second surface opposite to the first surface, where the first surface is attached to the second carrier by the second adhesive, and a first adhesive residue is formed on the second surface. A light shielding layer is formed on the at least two light emitting elements and the first adhesive residues, where the light shielding layer fills a gap between the at least two light emitting elements. The first adhesive residues and a portion of the light shielding layer are removed to expose the second surfaces. An array substrate is provided and the at least two light emitting elements are transferred from the second carrier to the array substrate after exposing the second surfaces, where the second surfaces face the array substrate.

The display device according to at least one embodiment of the present disclosure includes an array substrate, light emitting elements and light shielding units. The light emitting elements are disposed on the array substrate and electrically connected to the array substrate, where each of the light emitting elements has a first surface and a second surface opposite to the first surface. The second surfaces face the array substrate. The light shielding units are disposed on the array substrate and arranged alternately with the light emitting elements, where the light shielding units expose the first surfaces, and each of the light shielding units has a top and a bottom opposite to the top. The bottoms face the array substrate, and a cavity is existed between the bottoms and the array substrate.

The display device according to at least another embodiment of the present disclosure includes an array substrate, light emitting elements and light shielding units. The light emitting elements are disposed on the array substrate and electrically connected to the array substrate, where each of the light emitting elements has a first surface and a second surface opposite to the first surface. The second surfaces face the array substrate. The light shielding units are disposed on the array substrate and arranged alternately with the light emitting elements, where the light shielding units expose the first surfaces. Each of the light shielding units has a top and a bottom opposite to the top, where the bottom faces the array substrate, and the bottom includes a curved surface.

### BRIEF DESCRIPTION OF THE DRAWINGS

FIGS. 1A to 1G are schematic cross-sectional views of a method of manufacturing a display device according to at least one embodiment of the present disclosure.

FIG. 2 is a schematic cross-sectional view of a display device according to at least one embodiment of the present disclosure.

FIG. 3 is a schematic cross-sectional view of a display device according to at least another embodiment of the present disclosure.

FIG. 4 is a schematic cross-sectional view of a display device according to at least another embodiment of the present disclosure.

FIGS. 5A to 5G are schematic cross-sectional views of a method of manufacturing a display device according to at least another embodiment of the present disclosure.

FIG. 6 is a schematic cross-sectional view of a display device according to at least another embodiment of the present disclosure.

FIG. 7 is a schematic cross-sectional view of a display device according to at least another embodiment of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Although a series of operations or steps are used to illustrate the manufacturing method in the present disclosure, the order shown in these operations or steps should not be construed as a limitation of the present disclosure. For example, some operations or steps may be performed in a different order and/or concurrently with other steps. In addition, each operation or step described herein may include several sub-steps or actions.

Moreover, the present disclosure may be implemented or applied in various other specific embodiments, and the details of the present disclosure may be combined, modified, and altered in various embodiments based on different viewpoints and applications, without departing from the idea of the present disclosure.

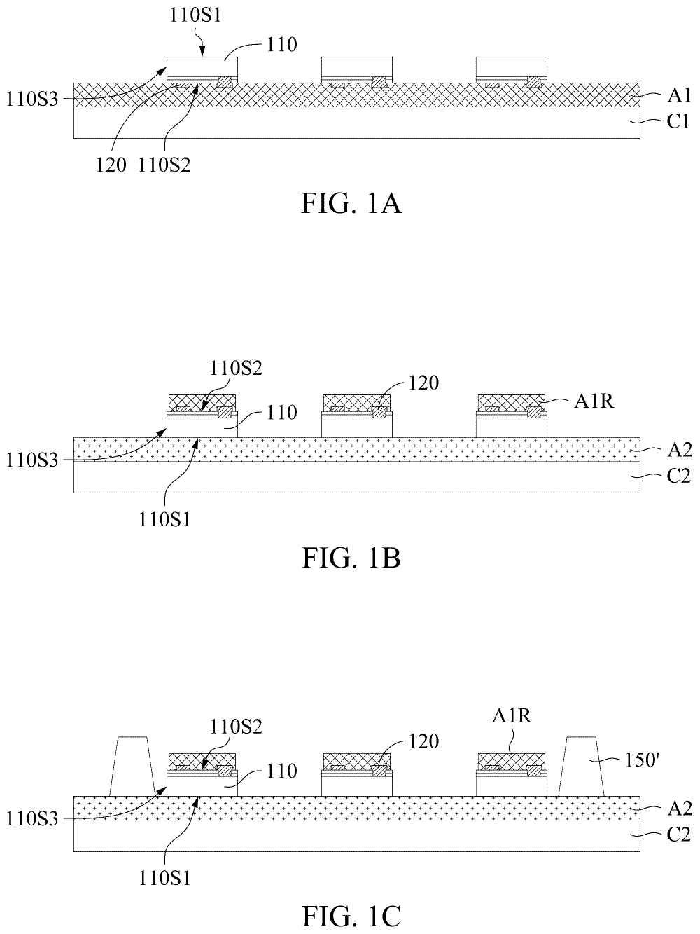

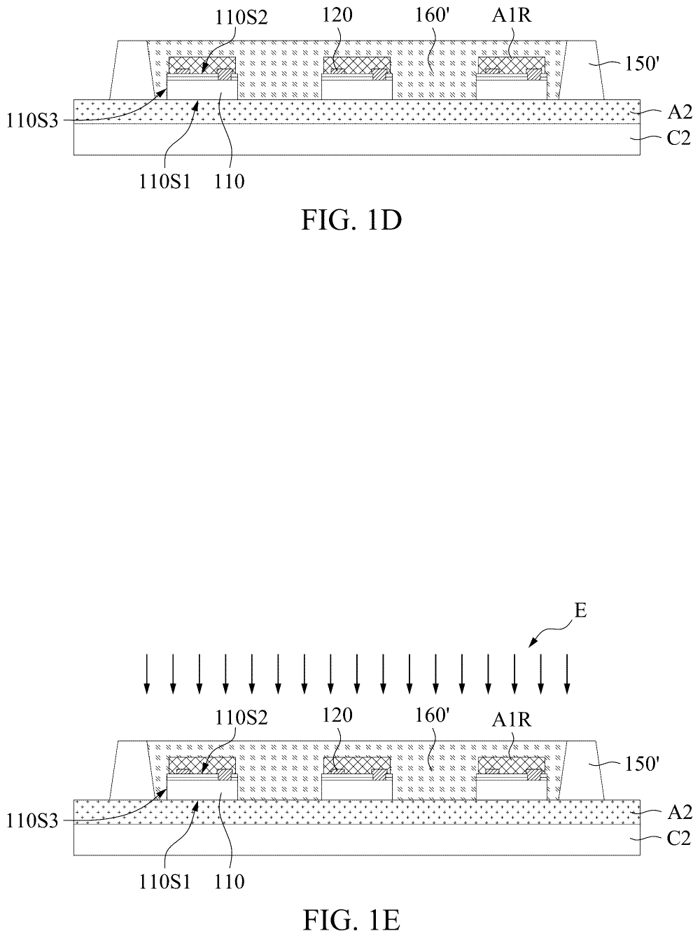

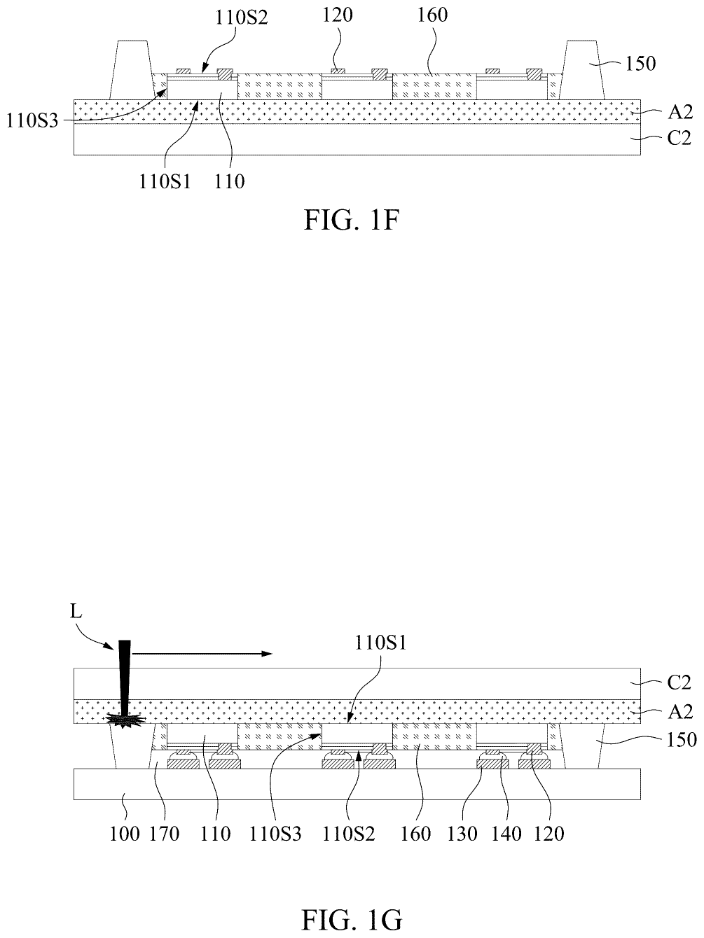

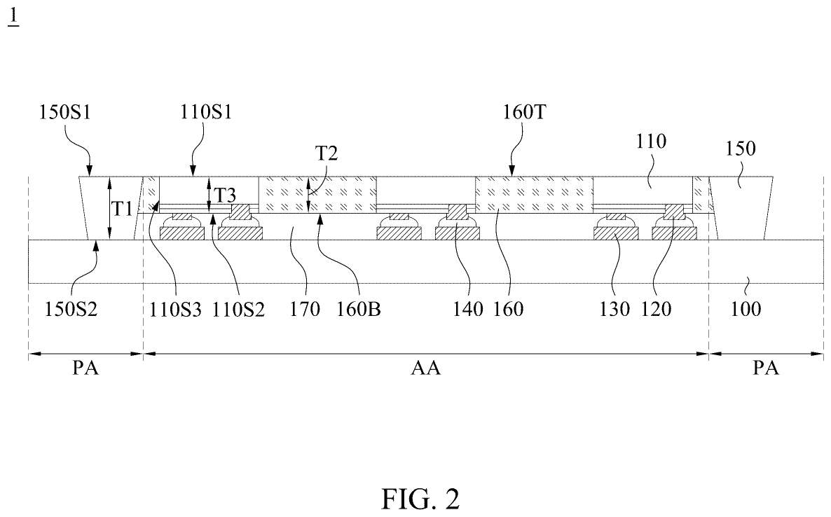

FIGS. 1A to 1G are schematic cross-sectional views of a method of manufacturing a display device according to at least one embodiment of the present disclosure. FIG. 2 is a schematic cross-sectional view of a display device according to at least one embodiment of the present disclosure. Referring to FIG. 1A, a first carrier C1, a first adhesion A1 and light emitting elements 110 are provided. The first adhesion A1 is disposed between the light emitting elements 110 and the first carrier C1, and attaches the light emitting elements 110 to the first carrier C1. In some embodiments, the first carrier C1 may be a wafer substrate, a glass substrate, a ceramic substrate or a plastic substrate. In this embodiment, the first carrier C1 is a plastic substrate for carrying the light emitting elements 110 transferred from the wafer substrate, but is not limited thereto. In some embodiments, the first adhesion A1 may be an optical adhesion or a pressure-sensitive adhesion. In some embodiments, the material of the first adhesion A1 may include epoxy.

In some embodiments, the light emitting elements 110 may be light emitting diodes (LEDs), such as sub-millimeter light emitting diodes (mini LEDs) or micro light emitting diodes (micro LEDs, μLEDs). The thickness of the micro light emitting diode is below 10 micrometers, for example 6 micrometers. Sub-millimeter light emitting diodes can be divided into two types: one contains encapsulant and the other does not contain encapsulant. The thickness of sub-millimeter light emitting diode containing encapsulant can be less than 800 micrometers, and the thickness of sub-millimeter light emitting diode without encapsulant can be less than 100 micrometers. In addition, the light emitting elements 20 can also be large-sized regular LEDs other than sub-millimeter light emitting diodes and micro light emitting diodes, so the light emitting elements 20 are not limited to being sub-millimeter light emitting diodes or micro light emitting diodes of smaller size.

As shown in FIG. 1A, each of the light emitting elements 110 has a first surface 110S1, a second surface 110S2 opposite the first surface 110S1, and a side surface 110S3 connecting the first surface 110S1 and the second surface 110S2. Soldering pads 120 are disposed on the second surfaces 110S2 of the light emitting elements 110. In some embodiments, the first surfaces 110S1 of the light emitting element 110 are the light emitting surfaces of the light emitting elements 110.

Referring to FIG. 1B, a second carrier C2 and a second adhesion A2 are provided, and the second adhesion A2 is disposed on the second carrier C2. In some embodiments, the second carrier C2 may be a glass substrate, a ceramic substrate or a plastic substrate. In this embodiment, the second carrier C2 is a plastic substrate for carrying and positioning the light emitting elements 110 transferred from the first carrier C1 to fix the sub-pixel pitch for bonding to the array substrate, but is not limited thereto. In some embodiments, the second adhesion A2 may be an optical adhesion or a pressure-sensitive adhesion. In some embodiments, the material of the second adhesion A2 may include silica gel.

As shown in FIG. 1B, the light emitting elements 110 are transferred from the first carrier C1 to the second carrier C2, and the first surfaces 110S1 of the light emitting elements 110 are attached to the second carrier C2 through the second adhesion A2, where first adhesion residues A1R are formed on the second surfaces 110S2 of the light emitting elements 110. In some embodiments, the method of transferring the light emitting elements 110 from the first carrier C1 to the second carrier C2 may include a laser lift-off process.

Referring to FIG. 1C, one or multiple spacer layers 150′ are formed on the second carrier C2. In some embodiments, the material of the one or multiple spacer layers 150′ may include photoresist. In some embodiments, the one or multiple spacer layers 150′ may be formed by an inkjet process, a printing process, a coating process, and a photolithography process. As shown in FIG. 1C, the height of the spacer layer 150′ is greater than the sum of the heights of the light emitting element 110 and the first adhesion residue A1R. In other words, the spacer layer 150′ protrudes from the upper surface of the first adhesion residue A1R. In some embodiments, the one or multiple spacer layers 150′ may be used to define a fill range for a light shielding layer, as well as to act as support elements between the second carrier C2 and the array substrate when the light emitting elements 110 are transferred from the second carrier C2 to the array substrate. In some embodiments, the one or multiple spacer layers 150′ may include a ring structure, a mesh structure, a column structure, or a combination thereof.

Referring to FIG. 1D, a light shielding layer 160′ is formed on the light emitting elements 110 and the first adhesion residues A1R, and fills the gaps between the light emitting elements 110. In some embodiments, the material of the light shielding layer 160′ may include phenol formaldehyde resin, epoxy resin, catalyst, silicon oxide, dark-colored photoresist, or a combination thereof. In some embodiments, the light shielding layer 160′ may be formed by a deposition process, an inkjet process, a printing process or a coating process.

Next, as shown in FIG. 1E and FIG. 1F, etching E is performed to remove the first adhesion residues A1R and a portion of the light shielding layer 160′ to expose the second surfaces 110S2 of the light emitting elements 110. In some embodiments, the method of removing the first adhesion residues A1R and a portion of the light shielding layer 160′ may be dry etching, such as plasma etching using a mixed gas of sulfur hexafluoride (SF6) and oxygen.

In some embodiments, the etching rate of the one or multiple spacer layers 150′ is less than the etching rate of the light shielding layer 160′, and the etching rate of the light shielding layer 160′ is less than or equal to the etching rate of the first adhesion residues A1R. In other words, the etching rate of the one or multiple spacer layers 150′ is less than the etching rate of the light shielding layer 160′, and the etching rate of the light shielding layer 160′ is less than or equal to the etching rate of the first adhesion A1. In some embodiments, the above-mentioned etching rate relationship can be achieved by selecting materials, it can also be achieved by adjusting the process, such as the temperature or the time of baking.

As shown in FIG. 1F, the one or multiple spacer layers 150′ are formed into one or multiple spacers 150 after etching, the light shielding layer 160′ is formed into light shielding units 160 after etching, and the first adhesion residues A1R are removed after etching, thereby exposing the second surfaces 110S2 of the light emitting elements 110. The height of the spacer 150 is greater than the height of the light emitting element 110 and the height of the light shielding unit 160. In some embodiments, the one or multiple spacers 150 may be used to act as support elements between the second carrier C2 and the array substrate when the light emitting elements 110 are transferred from the second carrier C2 to the array substrate. In some embodiments, the one or multiple spacers 150 may include a ring structure, a mesh structure, a column structure, or a combination thereof.

Referring to FIG. 1G, an array substrate 100 is provided, and after exposing the second surfaces 110S2 of the light emitting elements 110, the light emitting elements 110 are transferred from the second carrier C2 to the array substrate 100, where the second surfaces 110S2 of the light emitting elements 110 face the array substrate 100. In some embodiments, the array substrate 100 may include elements or circuit lines required for the display device 1, such as driver elements, switch elements, power lines, drive signal lines, timing signal lines, current compensation lines, detection signal lines. For example, a deposition process, a photolithography and an etching process can be used to form the elements or the circuit lines required for the display device 1.

As shown in FIG. 1G, bonding pads 130 are formed on the array substrate 100 to electrically connect to the soldering pads 120 formed on the second surfaces 110S2 of the light emitting elements 110, thereby bonding the light emitting elements 110 to the array substrate 100. In detail, after forming solders 140 on the soldering pads 120 and aligning the second carrier C2 with the array substrate 100, the second adhesion A2 is irradiated by laser L to lift-off the light emitting elements 110 from the second carrier C2. At the same time, the solders 140 can be soldered to the soldering pads 120 and the bonding pads 130 to bond the light emitting elements 110 and the array substrate 100, but are not limited to this. The solders 140 can be formed on the soldering pads 120 before the light emitting elements 110 are transferred to the first carrier C1. In some embodiments, the bonding pads 130 can be formed on the array substrate 100 by electroless plating (e.g., chemical plating) process. The material of the bonding pads 130 can include nickel-gold alloy. The material of the solders 140 may include metals suitable for eutectic soldering, such as tin, indium and bismuth, so as to form eutectic bond with the bonding pads 130 by laser.

Referring to FIG. 1G and FIG. 2, the display device 1 includes an array substrate 100, light emitting elements 110 and light shielding units 160. The light emitting elements 110 are disposed on the array substrate 100 and electrically connected to the array substrate 100. Each of the light emitting elements 110 has a first surface 110S1 and a second surface 110S2 opposite to the first surface. The second surfaces 110S2 face the array substrate 100. The light shielding units 160 are disposed on the array substrate 100 and may be arranged alternately with the light emitting elements 110. The light shielding units 160 expose the first surfaces 110S1 of the light emitting elements 110, and the first surfaces 110S1 are the light emitting surfaces of the light emitting elements 110. Each of the light shielding units 160 has a top 160T and a bottom 160B opposite to the top 160T. The bottoms 160B face the array substrate 100, and a cavity 170 is included between the bottoms 160B and the array substrate 100. In some embodiments, the cavity 170 may be an air layer.

By forming the light shielding layer 160′ on the light emitting elements 110 and on the first adhesion residues A1R, and filling the gaps between the light emitting elements 110, the second adhesion A2 can be protected. When removing the first adhesion residues A1R by etching, the chance of the second adhesion A2 being damaged is reduced, which in turn reduces the chance of the light emitting elements 110 being shifted and dark spots occurring when they are bonded to the array substrate 100, and thus improves the yield. Moreover, the cavity 170 is existed between the bottoms 160B of the light shielding units 160 and the array substrate 100 as a result of the above-mentioned process, which prevents light mixing of the light emitting elements 110 that emit different colors of light, and thus reduces light crosstalk.

Referring to FIG. 2, the display device 1 has a display area AA and a peripheral area PA surrounding the display area AA, the light emitting elements 110 are disposed in the display area AA, and the spacers 150 are disposed in the peripheral area PA. In some embodiments, the thickness T1 of the spacer 150 is greater than the thickness T2 of the light shielding unit 160, and the thickness T2 of the light shielding unit 160 is greater than or equal to the thickness T3 of the light emitting element 110. As shown in FIG. 2, the spacer 150 has a bottom surface 150S2 that facing the array substrate 100 and a top surface 150S1 opposite to the bottom surface 150S2, where the top surface 150S1 is larger than the bottom surface 150S2.

As shown in FIG. 1G and FIG. 2, the thickness T1 of the spacer 150 is greater than the thickness T2 of the light shielding unit 160, and the bottom 160B of the light shielding unit 160 is approximately flush with the second surface 110S2 of the light emitting element 110. Therefore, in this embodiment, the etching rate of the one or multiple spacer layers 150′ is smaller than the etching rate of the light shielding layer 160′, and the etching rate of the light shielding layer 160′ is equal to the etching rate of the first adhesion residues A1R, i.e., the etching rate of the light shielding layer 160′ is equal to the first adhesion A1.

In some embodiments, the first surfaces 110S1 of the light emitting elements 110 protrude from the tops 160T of the light shielding units 160. In some embodiments, the first surface 110S1 of the light emitting element 110 may include a rough structure to enhance the light extraction rate. In some embodiments, in addition to contacting the side surface 110S3 of the light emitting element 110, the light shielding unit 160 can also extend to a portion of the second surface 110S2 of the light emitting element 110 adjacent to the side surface 110S3, which can further reduce light crosstalk.

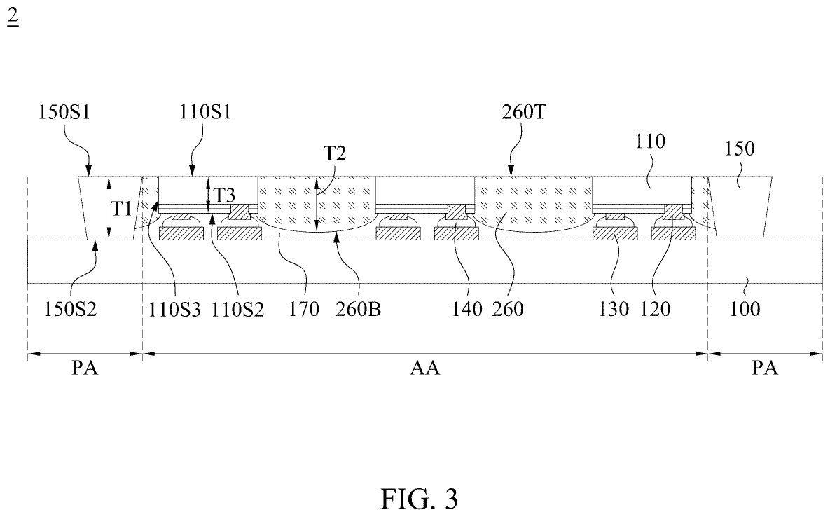

FIG. 3 is a schematic cross-sectional view of a display device according to at least another embodiment of the present disclosure. The structures, the materials, the manufacturing processes and the relative positions of most elements in the embodiments of FIG. 3 and FIG. 2 are the same, so the same features are not repeated here. The difference between the embodiments of FIG. 3 and FIG. 2 is that the light shielding unit 260 of the display device 2 includes a top 260T and a bottom 260B opposite to the top 260T, where the bottom 260B includes a curved surface, and the curved surface is a convex surface protruding from the light emitting elements 110.

In detail, the bottom 260B of the light shielding unit 260 protrudes from the second surface 110S2 of the light emitting element 110, the thickness T1 of the spacer 150 is greater than the thickness T2 of the light shielding unit 260, and the thickness T2 of the light shielding unit 260 is greater than the thickness T3 of the light emitting element 110. Therefore, in this embodiment, the etching rate of the one or multiple spacer layers 150′ is less than the etching rate of the light shielding layer 160′, and the etching rate of the light shielding layer 160′ is less than the etching rate of the first adhesion residues A1R, that is, the etching rate of the light shielding layer 160′ is less than the etching rate of the first adhesion A1. Through the above-mentioned structural design and material selection or process adjustment, light crosstalk can be further reduced.

In some embodiments, the thickness difference between the light shielding unit 260 and the light emitting element 110 is less than or equal to the thickness difference between the spacer 150 and the light emitting element 110, so that the light emitting element 110 can be successfully bonded to the array substrate 100. In some embodiments, the thickness of the bonding pad 130 formed on the array substrate 100 is approximately equal to the thickness difference between the spacer 150 and the light shielding unit 260, so that the light emitting element 110 can be successfully bonded to the array substrate 100.

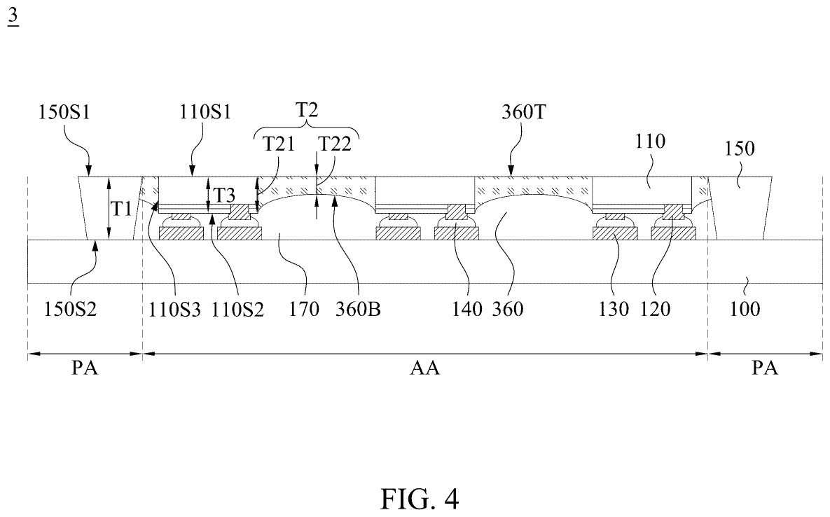

FIG. 4 is a schematic cross-sectional view of a display device according to at least another embodiment of the present disclosure. The structures, the materials, the manufacturing processes and the relative positions of most elements in the embodiments of FIG. 4 and FIG. 2 are the same, so the same features are not repeated here. The difference between the embodiments of FIG. 4 and FIG. 2 is that the light shielding unit 360 of the display device 3 includes a top 360T and a bottom 360B opposite to the top 360T, where bottom 360B includes a curved surface, and the curved surface is a concave surface. The light emitting elements 110 protrude from the concave surface.

In detail, the second surface 110S2 of the light emitting element 110 protrudes from the bottom 360B of the light shielding unit 360, the thickness T1 of the spacer 150 is greater than the thickness T2 of the light shielding unit 360. The thickness T21 of the edges of the light shielding unit 360 is greater than or equal to the thickness T3 of the light emitting element 110, and the thickness T22 of the center of the light shielding unit 360 is less than the thickness T3 of the light emitting element 110. Therefore, in this embodiment, the etching rate of the one or multiple spacer layers 150′ is less than the etching rate of the light shielding layer 160′, and the etching rate of the light shielding layer 160′ is greater than the etching rate of the first adhesion residues A1R, that is, the etching rate of the light shielding layer 160′ is greater than the etching rate of the first adhesion A1. Through the above-mentioned structural design and material selection or process adjustment, light crosstalk can be further reduced.

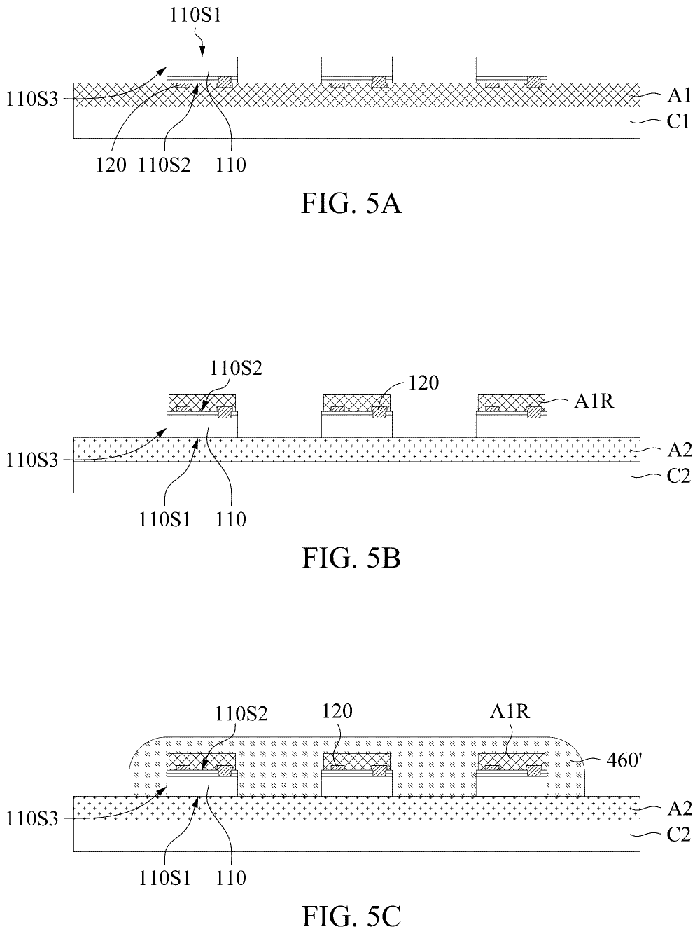

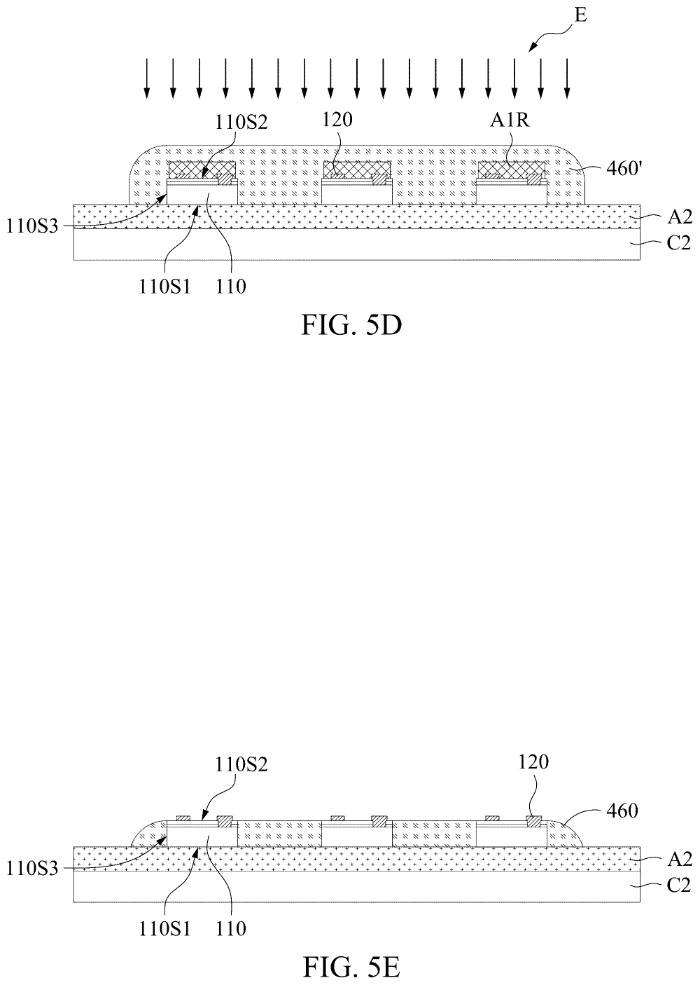

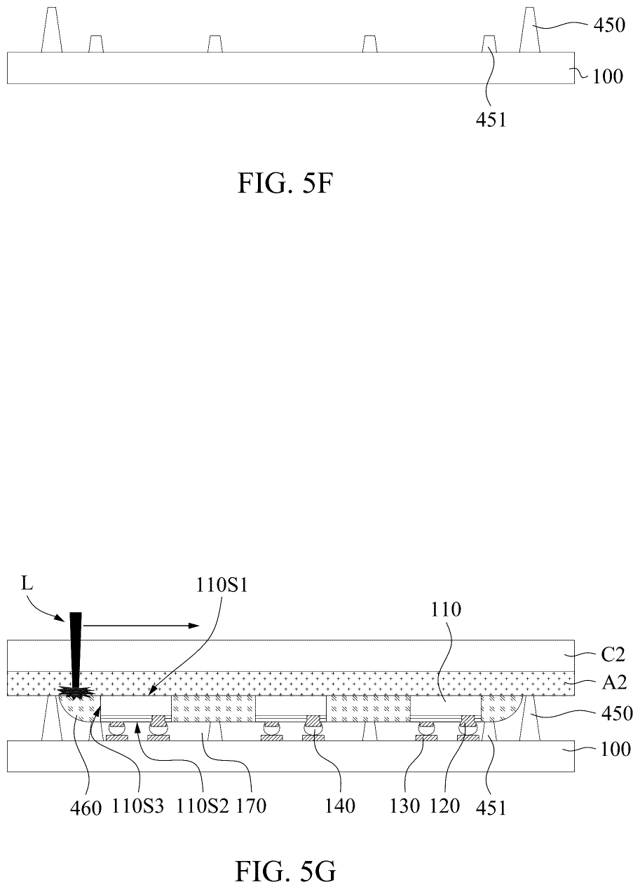

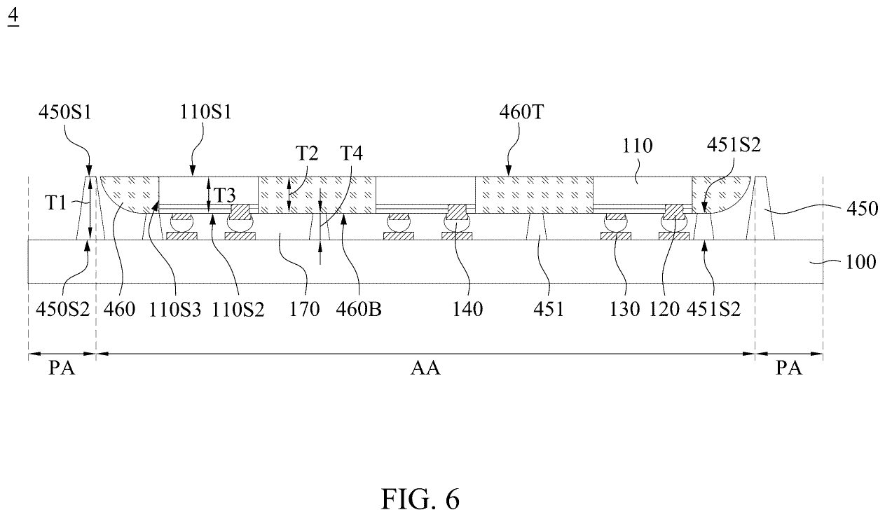

FIGS. 5A to 5G are schematic cross-sectional views of a method of manufacturing a display device according to at least another embodiment of the present disclosure. FIG. 6 is a schematic cross-sectional view of a display device according to at least another embodiment of the present disclosure. The structures, the materials, the manufacturing processes and the relative positions of most elements in the embodiments of FIGS. 5A to 5G, FIG. 6, FIGS. 1A to 1G and FIG. 2 are the same, so the same features are not repeated here. The differences between the two embodiments are described below.

Referring to FIG. 5C to FIG. 5F, the difference from FIG. 1C to FIG. 1F is that, as shown in FIG. 5C, a light shielding layer 460′ is formed on the light emitting element 110 and on the first adhesion residues A1R, and fills the gaps between the light emitting elements 110, but no spacer layer is formed. Next, as shown in FIG. 5D and FIG. 5E, etching E is performed to remove the first adhesion residues A1R and a portion of the light shielding layer 460′ to expose the second surfaces 110S2 of the light emitting elements 110. In detail, the light shielding layer 460′ is formed into light shielding units 460 after etching, and the first adhesion residues A1R are removed after etching to expose the second surfaces 110S2 of the light emitting elements 110.

Next, as shown in FIG. 5F, an array substrate 100 is provided and one or multiple first spacers 450 and one or multiple second spacers 451 are formed on the array substrate 100. The height of the first spacer 450 is greater than the height of the second spacer 451. As shown in FIG. 5G, after exposing the second surfaces 110S2 of the light emitting elements 110, the light emitting elements 110 are transferred from the second carrier C2 to the array substrate 100, where the second surfaces 110S2 of the light emitting elements 110 face the array substrate 100. In some embodiments, during the transfer of the light emitting elements 110 from the second carrier C2 to the array substrate 100, the first spacers 450 contact the second adhesion A2 and the second spacers 451 contact the light shielding units 460, where the first spacers 450 and the second spacers 451 serve as support elements between the second carrier C2 and the array substrate 100.

Referring to FIG. 6, the first spacers 450 of the display device 4 are disposed in the peripheral area PA, the second spacers 451 are disposed in the display area AA and in contact with the light shielding units 460. The thickness T1 of the first spacer 450 is greater than the thickness T4 of the second spacer 451. The first spacer 450 and the second spacer 451 respectively have the bottom surfaces 450S2, 451S2 facing the array substrate 100 and the top surfaces 450S1, 451S1 respectively opposite the bottom surfaces 450S2, 451S2. The bottom surfaces 450S2, 451S2 are respectively larger than the top surfaces 450S1, 451S1.

In some embodiments, as shown in FIG. 6, in the display device 4, a spacing is existed between the first spacer 450 and the top 460T of the light shielding unit 460 closest to the first spacer 450, and the bottom 460B of the light shielding unit 460 closest to the first spacer 450 has a curved edge.

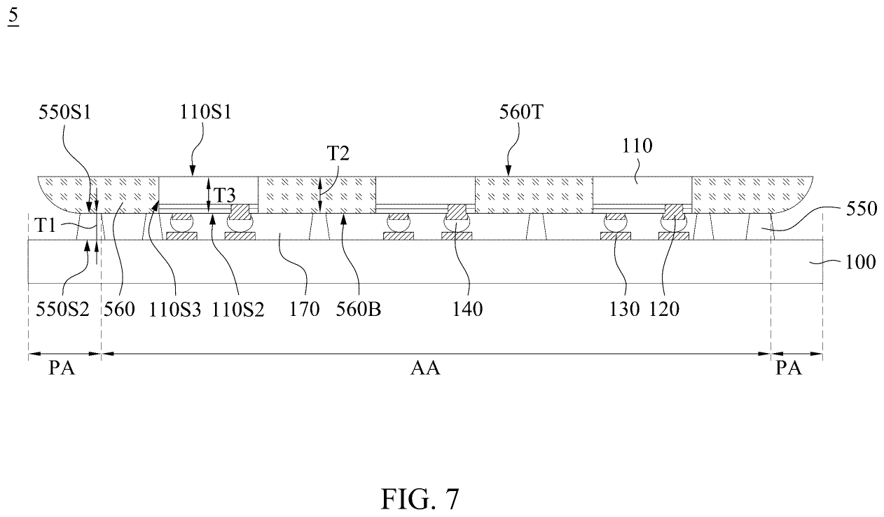

FIG. 7 is a schematic cross-sectional view of a display device according to at least another embodiment of the present disclosure. The structures, the materials, the manufacturing processes and the relative positions of most elements in the embodiments of FIG. 7 and FIG. 6 are the same, so the same features are not repeated here. The difference between the embodiments of FIG. 7 and FIG. 6 is that the light shielding units 560 of the display device 5 are not only located in the display area AA, but also extends to the peripheral area PA, even close to the edge of the display device 5. Each of the light shielding units 560 has a top 560T and a bottom 560B opposite to the top 560T. In addition, the display device 5 includes spacers 550 in contact with the light shielding units 560, and each of the spacers 550 has the bottom surface 550S2 facing the array substrate 100 and the top surface 550S1 opposite the bottom surface 550S2. The spacers 550 located in the display area AA and the peripheral area PA are with the same thicknesses. That is, the display device 5 does not include spacers with different thicknesses located in the display area AA and the peripheral area PA respectively.

In summary, in at least one embodiment of the display device and the method of manufacturing the same of the present disclosure, by forming the light shielding layer on the light emitting elements and on the adhesion residues, and filling the gaps between the light emitting elements, the adhesion between the carrier and the light emitting elements can be protected. When removing the adhesion residues by etching, the chance of the adhesion between the carrier and the light emitting elements being damaged is reduced, thereby reducing the chance of the light emitting elements being shifted and dark spots occurring when they are bonded to the array substrate, and thus improves the yield. Moreover, the cavity is existed between the bottoms of the light shielding units and the array substrate as a result of the above-mentioned process, which prevents light mixing of the light emitting elements that emit different colors of light, and thus reduces light crosstalk.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A method of manufacturing a display device, comprising:
providing a first carrier, a first adhesive and a plurality of light emitting elements, wherein the first adhesive is disposed between the light emitting elements and the first carrier, and attaches the light emitting elements to the first carrier;
providing a second carrier and a second adhesive, wherein the second adhesive is disposed on the second carrier;
transferring at least two of the light emitting elements from the first carrier to the second carrier, each of the at least two light emitting elements having a first surface and a second surface opposite to the first surface, wherein the first surface is attached on the second carrier by the second adhesive, and a first adhesive residue is formed on the second surface;
forming a light shielding layer on the at least two light emitting elements and the first adhesive residues, wherein the light shielding layer fills a gap between the at least two light emitting elements;
removing the first adhesive residues and a portion of the light shielding layer to expose the second surfaces; and
providing an array substrate and transferring the at least two light emitting elements from the second carrier to the array substrate after exposing the second surfaces, wherein the second surfaces face the array substrate.

2. The method of claim 1, further comprising forming one or multiple spacer layer on the second carrier before forming the light shielding layer.

3. The method of claim 2, wherein removing the first adhesive residues and a portion of the light shielding layer comprises dry etching, wherein an etching rate of the one or multiple spacer layers is less than an etching rate of the light shielding layer, and the etching rate of the light shielding layer is less than or equal to an etching rate of the first adhesive.

4. A display device, comprising:
an array substrate;
a plurality of light emitting elements, disposed on the array substrate and electrically connected to the array substrate, wherein each of the light emitting elements has a first surface and a second surface opposite to the first surface, the second surfaces face the array substrate; and
a plurality of light shielding units, disposed on the array substrate and arranged alternately with the light emitting elements, wherein the light shielding units expose the first surfaces, each of the light shielding units has a top and a bottom opposite to the top, the bottoms face the array substrate, and a cavity is existed between the bottoms and the array substrate.

5. The display device of claim 4, further comprising one or multiple spacers disposed on the array substrate, wherein a thickness of each of the one or multiple spacers is greater than a thickness of each of the light shielding units, and each of the one or multiple spacers has a bottom surface and a top surface opposite to the bottom surface, wherein the top surface is larger than the bottom surface.

6. The display device of claim 4, further comprising one or multiple spacers disposed on the array substrate, wherein each of the one or multiple spacers has a bottom surface and a top surface opposite to the bottom surface, and the bottom surface is larger than the top surface.

7. The display device of claim 6, further having a display area and a peripheral area around the display area, wherein the spacers comprise one or multiple first spacers disposed in the peripheral area and one or multiple second spacers disposed in the display area, and a thickness of each of the one or multiple first spacers is greater than a thickness of each of the one or multiple second spacers.

8. The display device of claim 4, wherein each of the light emitting elements further has a side surface connecting the first surface and the second surface, wherein the light shielding units are in contact with the side surfaces and extend to a portion of the second surfaces.

9. The display device of claim 4, wherein the bottom comprises a curved surface.

10. The display device of claim 9, wherein the curved surface is a convex surface, and the convex surface protrudes from the light emitting elements.

11. The display device of claim 9, wherein the curved surface is a concave surface, and the light emitting elements protrude from the concave surface.

12. A display device, comprising:
an array substrate;
a plurality of light emitting elements, disposed on the array substrate and electrically connected to the array substrate, wherein each of the light emitting elements has a first surface and a second surface opposite to the first surface, the second surfaces face the array substrate; and
a plurality of light shielding units, disposed on the array substrate and arranged alternately with the light emitting elements, wherein the light shielding units expose the first surfaces, each of the light shielding units has a top and a bottom opposite to the top, the bottom faces the array substrate, and the bottom comprises a curved surface.

13. The display device of claim 12, wherein the curved surface is a convex surface, and the convex surface protrudes from the light emitting elements.

14. The display device of claim 12, wherein the curved surface is a concave surface, and the light emitting elements protrude from the concave surface.

15. The display device of claim 12, wherein each of the light emitting elements further has a side surface connecting the first surface and the second surface, wherein the light shielding units are in contact with the side surfaces and extend to a portion of the second surfaces.
